(19) United States
(12) Patent Application Publication
(10) Pub. No.: US 2015/0380586 A1
(43) Pub. Date: Dec. 31, 2015

(54) LAMINATED SHEET AND BACK SHEET FOR SOLAR CELL MODULES

(71) Applicant: FUJIFILM Corporation, Tokyo (JP)

(72) Inventor: Akira HATAKEYAMA, Shizuoka (JP)

(73) Assignee: FUJIFILM Corporation, Tokyo (JP)

(21) Appl. No.: 14/850,533

(22) Filed: Sep. 10, 2015

Related U.S. Application Data
(63) Continuation of application No. PCT/JP2014/056863, filed on Mar. 14, 2014.

(30) Foreign Application Priority Data
Mar. 15, 2013 (JP) 2013-053972

(51) Int. Cl. H01L 31/049

(52) U.S. Cl. CPC H01L 31/049

(57) ABSTRACT

A laminated film having a support containing polyolefin as a main component, a polymer layer with an optical density of 2.0 or more, and an overcoat layer containing at least one of silicone-based resin and fluorine-based resin has both weather resistance and lightfastness.

### CROSS-REFERENCE TO RELATED APPLICATIONS

This application is a Continuation of PCT International Application No. PCT/JP2014/056863, filed on Mar. 14, 2014, which claims priority under 35 U.S.C. Section 119(a) to Japanese Patent Application No. 2013-053972 filed on Mar. 15, 2013. Each of the above applications is hereby expressly incorporated by reference, in its entirety, into the present application.

### BACKGROUND OF THE INVENTION

1. Field of the Invention

The present invention relates to a laminated sheet, and to a back sheet for solar cell modules. Specifically, the present invention relates to a laminated sheet for forming a back sheet having both weather resistance and excellent lightfastness for use in solar cell modules.

2. Background Art

Solar cells do not emit carbon dioxide to generate electricity, and have been rapidly spreading as an environmentally friendly power generation system. A solar cell module is typically structured to include a front substrate disposed on the front-surface side where sunlight is incident, a substrate (or a back sheet as it is also called) disposed on the back-surface side opposite the sunlight-incident front-surface side, and solar cells disposed between the front substrate and the back sheet and containing solar cell elements sealed therein with a sealant. Materials such as an EVA (ethylene-vinyl acetate) resin seal the interface between the front substrate and the solar cells and between the solar cells and the back sheet.

The back sheet forming the solar cell module serves to prevent entry of moisture from the back surface of the solar cell module. The back sheet commonly uses materials such as glass and fluororesin. For cost and other considerations, it has become more common to use polyester as back sheet material. Some of such polyester back sheets for solar cell modules are formed by using a method that uses polyethylene terephthalate (PET) as a support, and attaches other polymer sheet to the support.

The environment in which such back sheets for solar cell modules are used is rather harsh, exposing the back sheet to severe weather, including the wind and rain and direct sunlight, for extended time periods. The back sheet is thus required to have lightfastness, in addition to being weather resistant (wet heat resistance, heat resistance). A problem of polyester film, however, is that the film suffers from poor strength when exposed to wet heat for extended time periods. The back sheet for solar cell modules using a polyester film with the support thus requires further improvements in order to sufficiently exhibit its function over extended time periods.

This problem is addressed by a method that uses polyolefin as support material, instead of a polyester film. For example, Patent Document 1 discloses a technique that uses an ultrahigh-molecular-weight polyethylene support with an average molecular weight of 1000000 or more. While the method actually improves the wet heat resistance of the support, it requires further improvements in lightfastness. Specifically, improvements are needed not to cause coloring or strength decrease in the back sheet for solar cell modules during long outdoor use.

One way of improving lightfastness is to provide a UV absorbing layer on the outermost layer. For example, Patent Document 2 discloses a technique to provide an acrylic resin layer with a UV transmittance of 5% or less on the polyester film support.

### CITATION LIST

### Patent Documents

### Patent Document 1: JP-A-2011-35200

### Patent Document 2: JP-A-2010-92958

### SUMMARY OF INVENTION

The techniques of Patent Documents 1 and 2 may be combined to provide a UV absorber-containing acrylic resin layer on a polyolefin film. Lightfastness can improve to some extent this way. However, studies by the present inventor found that coloring or strength decrease occurs as the acrylic resin layer deteriorates itself after long outdoor use of the laminated sheet.

Accordingly, improvements are needed so that the power generating efficiency of the solar cell module does not deteriorate as a result of reduced light reflectance at the back sheet of the solar cell module upon coloring of the laminated film used as the back sheet. Improvements are also needed so that coloring does not spoil the overall design of the solar cell module.

The layers forming a laminated film may detach in the film when the film strength decreases, and the film may fail to sufficiently exhibit its function as a back sheet for solar cell modules. Improvements are also needed in this regard.

The present inventor conducted studies to solve the problems of related art, with the intention to provide a back sheet that does not undergo strength decrease or coloring due to wet heat or UV light even after long outdoor use. Specifically, it is an object of the present invention to provide a back sheet for solar cell modules which has both weather resistance and lightfastness.

After intensive studies to solve the foregoing problems, the present inventor found that a laminated film including a polyolefin-containing support, a polymer layer laminated on at least one surface of the support, and an overcoat layer laminated on the side of the polymer layer opposite the side with the support can have improved weather resistance and lightfastness when the polymer layer has an optical density of at least a certain value, and when a specific resin is used for the overcoat layer.

Specifically, the present invention has the following configurations.

[1] A laminated film containing a support, a polymer layer laminated on at least one surface of the support, and an overcoat layer laminated on a side of the polymer layer opposite the side with the support, wherein:

the support contains polyolefin as a main component,

the polymer layer has an optical density of 2.0 or more at 350 nm, and

the overcoat layer contains at least one of silicone-based resin and fluorine-based resin.

[2] The laminated film according to [1], wherein the polymer layer contains at least one binder resin selected from acrylic resin, polyester-based resin, polyurethane-based resin, polyolefinic resin, and silicone-based resin.

[3] The laminated film according to [1] or [2], wherein the polymer layer contains a UV absorber and a binder resin, the UV absorber being contained in 50 to 300 mass % with respect to the total mass of the binder resin.

[4] The laminated film according to any one of [1] to [3], wherein the polymer layer has an optical density of 2.5 or more at 350 nm.

[5] The laminated film according to any one of [1] to [4], wherein the polymer layer has an average thickness of 0.3 to 18 μm.

[6] The laminated film according to any one of [1] to [5], wherein the polymer layer is formed by being coated.

[7] The laminated film according to any one of [1] to [6], wherein at least one surface of the support is surface treated.

[8] The laminated film according to any one of [1] to [7], having a ΔYI of 10 or less, wherein the ΔYI represents an extent of yellowing of the laminated film with the formula (YI-2)−(YI-1), in which (YI-1) is the yellow chromaticity of the laminated film before ultraviolet irradiation, and (YI-2) is the yellow chromaticity of the laminated film after irradiation of ultraviolet light at an illuminance of 900 W/m² for 48 hours.

[9] A solar cell back sheet having the laminated film of any one of [1] to [8].

[10] A solar cell module having the solar cell back sheet of [9].

The present invention can provide a laminated film having both weather resistance and lightfastness. The laminated film of the present invention can preferably be used as a back sheet for solar cell modules used in severe environments such as outdoor.

### BRIEF DESCRIPTION OF DRAWINGS

FIG. 1 is a schematic cross sectional view of a laminated film of the present invention. In FIG. 1, 2 is support, 4 is polymer layer, 6 is overcoat layer and 10 is laminated film.

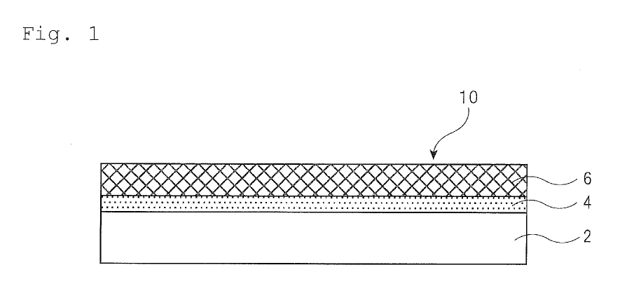

### DESCRIPTION OF EMBODIMENTS

The present invention is described below in detail. The descriptions of the constituting elements below, including the representative embodiments and concrete examples thereof according to the present invention, serve solely to illustrate the present invention, and the present invention is not limited by such embodiments and concrete examples. As used herein, numerical ranges with the preposition “to” are intended to be inclusive of the numbers defining the lower and upper limits of the ranges.

### (1. Laminated Film)

The present invention is concerned with a laminated film that includes a support, a polymer layer, and an overcoat layer. The polymer layer is laminated on at least one surface of the support, and the overcoat layer is laminated on the side of the polymer layer opposite the side with the support. In the present invention, other layers may be provided between the support, the polymer layer, and the overcoat layer. It is, however, preferable to laminate the support, the polymer layer, and the overcoat layer adjacent to each other, in this order.

In the laminated film of the present invention, the support contains polyolefin as a main component. The polymer layer has an optical density of 2.0 or more at 350 nm, and the overcoat layer contains at least one of silicone-based resin and fluorine-based resin.

Here, “main component” means a component contained in excess of 50 mass % of the polymer constituting the support. In the present invention, polyolefin accounts for at least 50 mass %, preferably at least 70 mass %, more preferably at least 90 mass %, further preferably 100 mass % of the polymer constituting the support.

By being configured as above, the laminated film of the present invention can have both weather resistance and lightfastness. The laminated film of the present invention can thus have reduced levels of coloring, and can maintain strength even when exposed to severe environment such as outdoor over extended time periods. Further, the laminated film of the present invention, with the excellent interlayer adhesion, generates few defects such as interlayer detachment, and can exhibit excellent functions as a back sheet for solar cell modules.

The extent of yellowing as might occur under UV light is preferably confined within a certain range in the laminated film of the present invention. In the present invention, ΔYI representing the extent of yellowing with the formula (YI-2)−(YI-1) is preferably 10 or less, where (YI-1) is the initial yellow chromaticity of the film (before UV irradiation), and (YI-2) is the yellow chromaticity of the laminated film after irradiation of UV light at an illuminance of 900 W/m² for 48 hours. ΔYI is preferably 10 or less, more preferably 8 or less, further preferably 5 or less. With these upper limits of ΔYI, the laminated film does not undergo yellowing even when the solar cell module is exposed to outdoor environment over extended time periods, and the film design can be improved.

### (2. Support)

### (2-1. Polyolefin)

The support constituting the laminated film of the present invention contains polyolefin as a main component. Examples of the polyolefins used in the present invention include polypropylene, polyethylene, polynorbornene, polymethylpentene, and copolymers containing these. Preferred for cost, mechanical strength, and durability are polypropylene and polyethylene.

Depending on the ways monomers are bonded together, the structure of polypropylene resin is broadly divided into three primary structures: an isotactic structure (the methyl groups are arranged on the same side), a syndiotactic structure (alternate arrangement), and an atactic structure (random arrangement). Isotactic polypropylene resins with the isotactic structure are produced with Ziegler-Natta catalyst or metallocene catalyst, and have high crystallinity with excellent mechanical properties, heat resistance, and barrier property. On the other hand, syndiotactic polypropylenes are produced only in the metallocene catalyst system in industrial production, and are less prevalent in industry because of their inability to produce highly crystalline resins. However, with the advancement of catalyst improvement techniques, it has become possible to produce syndiotactic polypropylenes of high crystallinity and high melting point in industrial production (see, for example, JP-A-2-41303, JP-A-2-274703, and JP-A-2-274704).

The primary structure of the polypropylene film is defined as being isotactic when it has more meso linkages, and syndiotactic when the film has more racemo linkages in ¹³C-NMR measuring how chains are bonded in a five-monomer unit. The film can be described in terms of a mesopentad fraction (mmmm), which represents the proportion of five-monomer units with all-meso linkages. Isotactic polypropylenes with higher mesopentad fractions have higher crystallinity and higher melting points. On the other hand, the film can be described in terms of a racemo pentad fraction (rrrr), which represents the proportion of five-monomer units with all-racemo linkages. The crystallinity, heat resistance, and mechanical properties improve as the racemo pentad fraction increases.

The syndiotactic polypropylene (hereinafter, also referred to as “SPP”) film used in the present invention is a film with a racemo pentad fraction of 70 to 99%. The racemo pentad fraction is preferably 30 to 97%, more preferably 70 to 85%. With a racemo pentad fraction of 30% or more, the heat resistance becomes desirable, and the film can preferably be used as a back sheet. The upper limit is concerned with the productivity of the resin in industrial production. The racemo pentad fraction does not pose problems in the film characteristics or the sheet characteristics of the present invention even when it is too high. However, with the current catalyst technique, polymerization characteristics greatly suffer when the racemo pentad fraction exceeds 99%. It is accordingly preferable for polymerization characteristics that the racemo pentad fraction be kept at about 97%.

Preferred for use as the polypropylene in the present invention are isotactic polypropylenes and syndiotactic polypropylenes.

The polyethylene resin is classified into high-density polyethylenes (specific gravity of about 0.92 to 0.96), low-density polyethylenes (specific gravity of about 0.91 to 0.92), and ultralow-density polyethylenes (specific gravity of 0.90 or less), according to its practical density. The present invention may preferably use any of these polyethylenes. Particularly preferred are high-density polyethylenes.

More preferably, the present invention may also use ultrahigh-molecular-weight polyethylenes with a molecular weight of 1000000 to 1500000, or even higher.

### (2-2. Support Thickness)

The polyolefin support of the present invention has a thickness of preferably 120 to 350 μm, more preferably 160 to 320 μm, particularly preferably 200 to 280 The dynamic strength becomes desirable with a thickness of 120 μm or more, whereas a thickness of 350 μm or less offers a cost advantage.

### (2-3. Surface Treatment of Support)

Preferably, the support is subjected to a surface treatment before applying the polymer layer (described later). The surface treatment may be any of, for example, a corona treatment, an ultraviolet treatment (UV treatment), a flame treatment, a low-pressure plasma treatment, an atmospheric plasma treatment, a sandblast treatment, and a chromic acid mixture treatment. The flame treatment may be performed according to methods that involve addition of silane compounds, as described in Japanese Patent No. 3893394 and JP-A-2007-39508. Preferred for convenience and environmental friendliness are corona treatment, flame treatment, atmospheric plasma treatment, and ultraviolet treatment (UV treatment).

The adhesion to the polymer layer tends to deteriorate when the support contains polyolefin, as compared to when it contains polyester. This is particularly the case when the polymer layer containing high concentrations of UV absorber is laminated on a polyolefin-containing support, and detachment may occur between these layers. However, in the present invention, the adhesion between the support and the polymer layer can be improved with the surface treatment performed on at least one surface of the polyolefin-containing support. The surface treatment also can prevent cissing when applying the polymer layer, and can provide desirable adhesion even when the layers are exposed to a wet heat environment.

### (3. Polymer Layer (Lightfastness Imparting Layer))

### (3-1. Optical Density)

The polymer layer (lightfastness imparting layer) constituting the laminated film of the present invention has an optical density of 2.0 or more at 350 nm. The optical density at 350 nm is 2.0 or more, preferably 2.5 or more, more preferably 3.0 or more. The upper limit of the optical density is not particularly limited. However, the amount of UV absorber in the polymer layer increases with an optical density of 4.0 or more, and the surface state or adhesion may deteriorate.

With the high optical density, the polymer layer can become functional as a lightfastness imparting layer. This improves the overall lightfastness of the laminated film. The laminated film with such excellent lightfastness does not suffer from defects such as coloring and strength decrease even after long outdoor use, and can desirably be used as a back sheet for solar cell modules.

The optical density can be determined as follows.

First, the optical density of an intact laminated film sample (a sample with the polymer layer and the overcoat layer) is calculated as optical density 1 from the equation below. The optical density is also calculated from the equation below for a sample prepared by detaching the polymer layer and the overcoat layer from the laminated film. This optical density is obtained as optical density 2.

Optical density=Log{(the intensity of 350 nm incident light on the laminated film from the overcoat layer side)/(the intensity of 350 nm light emerging from the side opposite the overcoat layer)}

From the optical density 1 and the optical density 2 calculated as above, the optical density of the polymer layer is calculated as follows.

Optical density of polymer layer=optical density 1−optical density 2

### (3-2. Polymer Layer Binder)

The polymer layer of the present invention preferably contains at least one binder resin selected from acrylic resin, polyester-based resin, polyurethane-based resin, polyolefinic resin, and silicone-based resin. Particularly preferred for use are acrylic resin and silicone-based resin.

The acrylic resin usable in the present invention is any of polymers of acrylic monomers such as methyl methacrylate, methyl acrylate, ethyl methacrylate, ethyl acrylate, butyl acrylate, 2-ethylhexyl acrylate, hydroxymethyl acrylate, hydroxyethyl acrylate, and glycidyl methyl acrylate, and copolymers of copolymerizable monomers with carboxylic acids such as acrylic acid, methacrylic acid, and itaconic acid, or with acrylic monomers such as styrene, acrylonitrile, vinyl acetate, acrylamide, and divinylbenzene.

Specific examples of preferred acrylic resins include a methyl methacrylate/methyl acrylate/ethyl methacrylate/acrylic acid copolymer, a methyl methacrylate/methyl acrylate/hydroxyethyl methacrylate/methacrylic acid copolymer, a methyl methacrylate/styrene/ethyl methacrylate/acrylic acid copolymer, a methyl methacrylate/2-ethylhexyl acrylate/hydroxyethyl methacrylate/acrylic acid copolymer, and a methyl methacrylate/styrene/2-ethylhexyl acrylate/hydroxyethyl methacrylate/acrylic acid copolymer.

The average molecular weight of the acrylic resin used in the present invention is preferably about 2000 to 200000, more preferably about 5000 to 150000.

The silicone-based resin usable in the present invention is a polymer having a (poly) siloxane structure of the following formula (1) within the molecular chain.

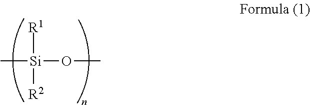

R¹ and R² in formula (1) each independently represent a hydrogen atom, a halogen atom, or a monovalent organic group. R¹ and R² may be the same or different, and a plurality of R¹ and R² may be the same or different. In the formula, n represents an integer of 1 or more. The monovalent organic group represented by R¹ and R² is a group capable of forming a covalent bond with the Si atom, and may be unsubstituted or substituted. Specific examples of the monovalent organic group include alkyl (e.g., such as methyl, and ethyl), aryl (e.g., such as phenyl), aralkyl (e.g., such as benzyl, and phenylethyl), alkoxy (e.g., such as methoxy, ethoxy, and propoxy), aryloxy (e.g., such as phenoxy), mercapto, amino (e.g., such as amino, and diethylamino), and amide.

Preferred as R¹ and R² are each independently a hydrogen atom, a chlorine atom, a bromine atom, unsubstituted or substituted alkyl of 1 to 4 carbon atoms (particularly, methyl, and ethyl), unsubstituted or substituted phenyl, unsubstituted or substituted alkoxy, mercapto, unsubstituted amino, and amide.

In formula (1) n is preferably 1 to 50000, more preferably 1 to 10000.

The proportion of the —(Si(R¹)(R²)—O)ₙ— moiety in the silicone-based resin of the present invention ((poly) siloxane structure unit represented by formula (1)) is preferably 15 to 95 mass %, more preferably 25 to 85 mass % with respect to the total mass of the silicone-based resin. Sufficient durability can be obtained when the proportion of the (poly)siloxane structure unit is 15 mass % or more. With a (poly)siloxane structure unit of 95 mass % or less, the coating solution can remain stable when being coated to form a silicone-containing polymer layer.

A moiety of the silicone-based resin of the present invention other than the —(Si(R¹)(R²)—O)ₙ— moiety may be formed of, for example, an acrylic or a polyester-based polymer forming a covalent bond with the —(Si(R¹)(R²)—O)ₙ— moiety. The moiety other than the —(Si(R¹)(R²)—O)ₙ— moiety is preferably an acrylic polymer. The acrylic polymer may have the same compositions and the same molecular weights as the acrylic resins described above.

The acrylic resin or the silicone-based resin used as the binder of the polymer layer may be soluble in an organic solvent, or may have a form of a latex with a water insoluble polymer dispersed in water. Preferably, the binder resin has a form of a latex in terms of reducing the environmental load during production. In this case, the polymer is preferably copolymerized with carboxylic acids such as acrylic acid, methacrylic acid, and itaconic acid.

Preferred examples of silicone-based resins include copolymers of a dimethyl dimethoxysilane/γ-methacryloxytrimethoxysilane hydrolysis condensation product and methyl methacrylate/ethyl acrylate/acrylic acid, copolymers of a dimethyl dimethoxysilane/diphenyl dimethoxysilane/γ-methacryloxytrimethoxysilane hydrolysis condensation product and methyl methacrylate/ethyl acrylate/acrylic acid, copolymers of a dimethyl dimethoxysilane/γ-methacryloxytrimethoxysilane hydrolysis condensation product and methyl methacrylate/ethyl acrylate/methacrylic acid, and copolymers of a dimethyl dimethoxysilane/diphenyl dimethoxysilane/γ-methacryloxytrimethoxysilane hydrolysis condensation product and methyl methacrylate/ethyl acrylate/styrene/methacrylic acid.

### (3-3. UV Absorber)

The UV absorber usable in the present invention may be, for example, an organic or an inorganic UV absorber.

Examples of organic UV absorbers include salicylic acid-, benzophenone-, benzotriazole-, cyanoacrylate-, and triazine-based UV absorbers, and UV stabilizers such as hindered amine.

Examples of salicylic acid-based UV absorbers include p-t-butylphenyl salicylate, and p-octylphenyl salicylate.

Examples of benzophenone-based UV absorbers include 2,4-dihydroxybenzophenone, 2-hydroxy-4-methoxybenzophenone, 2-hydroxy-4-methoxy-5-sulfobenzophenone, 2,2′,4,4′-tetrahydroxybenzophenone, and bis(2-methoxy-4-hydroxy-5-benzoylphenyl)methane.

Examples of benzotriazole-based UV absorbers include 2-(2′-hydroxy-5′-methylphenyl)benzotriazole, 2-(2′-hydroxy-5′-methylphenyl)benzotriazole, and 2,2′-methylenebis[4-(1,1,3,3-tetramethylbutyl)-6-(2H benzotriazol-2-yl)phenol].

Examples of cyanoacrylate-based UV absorbers include ethyl-2-cyano-3,3′-diphenyl acrylate.

Examples of triazine-based UV absorbers include 2-(4,6-diphenyl-1,3,5-triazin-2-yl)-5-[(hexyl)oxy]-phenol.

Examples of hindered amine-based UV stabilizers include bis(2,2,6,6-tetramethyl-4-piperidyl)sebacate, and dimethyl succinate.1-(2-hydroxyethyl)-4-hydroxy-2,2,6,6-tetramethylpiperidine polycondensate.

Other examples include nickel bis(octylphenyl)sulfide, and 2,4-di.t-butylphenyl-3′,5′-di.t-butyl-4′-hydroxybenzoate.

Preferred for use as UV absorbers are triazine-based UV absorbers for their high resistance to recurring UV absorption.

The inorganic UV absorbers may be fine particles, for example, such as titanium dioxide, and cerium oxide. For durability, it is preferable to use inorganic UV absorbers, particularly titanium dioxide.

In the present invention, the content of the UV absorber is preferably 50 to 300 mass % with respect to the total mass of the binder resin. The UV absorber content is preferably 60 mass % or more, more preferably 70 mass % or more, further preferably 90 mass % or more. The UV absorber content is preferably 280 mass % or less, more preferably 250 mass % or less, further preferably 230 mass % or less. With the UV absorber content falling in these ranges, the optical density of the polymer layer can be confined in the desired range, and the overall lightfastness of the laminated film can improve.

### (3-4. Other Components)

The polymer layer may contain other components, for example, such as crosslinkers, surfactants, and fillers.

Examples of the crosslinkers include epoxy-, isocyanate-, melamine-, carbodiimide-, and oxazoline-based crosslinkers. Preferably, the crosslinker is at least one selected from carbodiimide-based crosslinkers, oxazoline-based crosslinkers, and isocyanate-based crosslinkers.

The crosslinker is added in preferably 0.5 to 30 mass %, more preferably 3 to 15 mass % with respect to the binder constituting the polymer layer. With the crosslinker added in 0.5 mass % or more, a sufficient crosslinking effect can be obtained while maintaining the strength and the adhesion of the polymer layer. With a crosslinker content of 30 mass % or less, the coating solution can have an extended pot life.

The surfactants may be known surfactants, including anionic surfactants, and nonionic surfactants. When added, the surfactant is added in preferably 0.1 to 10 mg/m², more preferably 0.5 to 3 mg/m². With the surfactant added in 0.1 mg/m² or more, cissing can be reduced, and a desirable layer can be formed. With a surfactant content of 10 mg/m² or less, desirable adhesion can be achieved between the support and the polymer layer.

The polymer layer of the present invention may further contain a filler. The filler may be a known filler such as colloidal silica.

The filler content is preferably 20 mass % or less, more preferably 15 mass % or less with respect to the binder of the polymer layer. With a filler content of 20 mass % or less, the surface state of the polymer layer can be maintained even more desirably.

### (3-5. Polymer Layer Thickness)

Typically, the thickness of the polymer layer of the present invention is preferably 0.3 to 18 μm, more preferably 0.8 to 10 μm, further preferably 1.0 to 8 μm. With a polymer layer thickness of 0.3 μm or more, moisture permeation into the polymer layer from the polymer layer surface becomes less likely to occur under a wet heat environment. This makes it difficult for the moisture to reach the interface with the support, and the adhesion greatly improves. With a polymer layer thickness of 18 μm or less, the internal stress during the application and drying of the polymer layer itself can remain low, and the desirable adhesion can be obtained.

### (4. Overcoat Layer)

### (4-1. Overcoat Layer Binder)

The overcoat layer constituting the laminated film of the present invention contains at least one of silicone-based resin and fluorine-based resin. The silicone-based resin may be the same silicone-based resin described in conjunction with the binder of the polymer layer.

The fluorine-based resin is not particularly limited, as long as it is a polymer having a repeating unit represented by —(CFX¹—CX²X³)— (wherein X¹, X², and X³ represent a hydrogen atom, a fluorine atom, a chlorine atom, or a perfluoroalkyl group of 1 to 3 carbon atoms). Specific examples of the polymer include polytetrafluoroethylene (hereinafter, also referred to as “PTFE”), polyvinyl fluoride (hereinafter, also referred to as “PVF”), polyvinylidene fluoride (hereinafter, also referred to as “PVDF”), polychlorotrifluorideethylene (hereinafter, also referred to as “PCTFE”), and polytetrafluoropropylene (hereinafter, also referred to as “HFP”).

These polymers may be homopolymers of the same monomer, or copolymers of two or more fluoro polymers. Examples of such copolymers include a copolymer of tetrafluoroethylene and tetrafluoropropylene (“P(TFE/HFP)” for short), and a copolymer of tetrafluoroethylene and vinylidene fluoride (“P(TFE/VDF)” for short).

The fluorine-based resin may be a polymer obtained by a copolymerization of a fluorine-based monomer represented by —(CFX¹—CX²X³)— with other monomers. Examples of such copolymers include a copolymer of tetrafluoroethylene and ethylene (“P(TFE/E)” for short), a copolymer of tetrafluoroethylene and propylene (“P(TFE/P)” for short), a copolymer of tetrafluoroethylene and vinyl ether (“P(TFE/VE)” for short), a copolymer of tetrafluoroethylene and perfluoro vinyl ether (“P(TFE/FVE)” for short), a copolymer of chlorotrifluoroethylene and vinyl ether (“P(CTFE/VE)” for short), and a copolymer of chlorotrifluoroethylene and perfluoro vinyl ether (“P(CTFE/FVE)” for short).

Specific examples of preferred fluorine-based resins include a chlorotrifluoroethylene/perfluoroethyl vinyl ether copolymer, a chlorotrifluoroethylene/perfluoroethyl vinyl ether/methacrylic acid copolymer, a chlorotrifluoroethylene/ethyl vinyl ether copolymer, a chlorotrifluoroethylene/ethyl vinyl ether/methacrylic acid copolymer, a vinylidene fluoride/methyl methacrylate/methacrylic acid copolymer, and a vinyl fluoride/ethyl acrylate/acrylic acid copolymer. Particularly preferred are a chlorotrifluoroethylene/perfluoroethyl vinyl ether/methacrylic acid copolymer, and a chlorotrifluoroethylene/ethyl vinyl ether copolymer.

The fluorine-based resin may be used by being dissolved in an organic solvent, or may be used in a latex form as a dispersion of fluorine-based resin fine particles in water.

### (4-2. Other Component)

The overcoat layer may contain other components, for example, such as crosslinkers, surfactants, and fillers.

The crosslinkers, surfactants, and fillers may be the same crosslinkers, surfactants, and fillers described in conjunction with the other components of the polymer layer. These also may be used in the contents given above.

The overcoat layer may contain a lubricant. Examples of preferred lubricants include synthetic wax compounds, natural wax compounds, and surfactants. Specific examples of preferred lubricants include polyethylene wax, polypropylene wax, esters or amides of stearic acid and oleic acid, petroleum waxes (such as carnauba wax, Candelilla wax, paraffin wax, and microcrystalline wax), and montan wax.

The lubricant is contained in preferably 0.2 to 500 mg/m². With a lubricant content of 0.2 mg/m² or more, the scratch resistance can sufficiently improve by the effect of reducing the coefficient of kinetic friction with the lubricant. With a lubricant content of 500 mg/m² or less, the overcoat layer disposed on the outermost layer of the laminated film becomes unlikely to form a nonuniform coating or aggregates while being applied, and cissing defects become unlikely to occur.

### (4-3. Overcoat Layer Thickness)

Typically, the thickness of the overcoat layer of the present invention is preferably 0.5 to 10 μm, further preferably 0.8 to 8 μm, particularly preferably 1.0 to 5 μm. With an overcoat layer thickness of 0.5 μm or more, the polymer layer does not easily deteriorate under a wet heat environment. With an overcoat layer thickness of 10 μm or less, the internal stress during the application and drying of the overcoat layer itself can remain low, and the desirable adhesion can be obtained.

### (5. Laminated Film Producing Method)

A method for producing the laminated film of the present invention includes forming a polymer layer on at least one surface of a support, and forming an overcoat layer on the side of the polymer layer opposite the side with the support. Preferably, the formation of the polymer layer on the support is preceded by a surface treatment of the support surface where the polymer layer is to be formed.

### (5-1. Polymer Layer Forming Method)

The polymer layer of the present invention may be formed by using known methods such as coating and bonding. Preferably, the polymer layer is formed on the support by coating.

Coating may be performed by using known coating techniques, for example, such as gravure coating, and bar coating.

The coating solution may be an aqueous system using water as the coating solvent, or a solvent system using an organic solvent such as toluene, and methyl ethyl ketone. For environmental friendliness, it is preferable to use water as solvent. The coating solvent may be used alone or as a mixture of a water-miscible organic solvent with water. Examples of preferred coating solvents include water, water/ethyl alcohol=95/5 (mass ratio), and water/methyl cellosolve=97/3 (mass ratio).

### (5-2. Overcoat Layer Forming Method)

The overcoat layer of the present invention may be formed by using known methods such as coating and bonding.

Coating may be performed by using known coating techniques, for example, such as gravure coating, and bar coating. Preferably, the overcoat layer is formed on the polymer layer by coating. The coating methods and the coating solutions may be the same coating methods and the coating solutions as those described above.

### (5-3. Surface Treatment)

Preferably, the formation of the polymer layer on the support is preceded by a surface treatment.

Examples of the surface treatment include a corona treatment, an ultraviolet treatment (UV treatment), a flame treatment, a low-pressure plasma treatment, an atmospheric plasma treatment, a sandblast treatment, and a chromic acid mixture treatment. The flame treatment may be performed according to methods that involve addition of silane compounds, as described in Japanese Patent No. 3893394 and JP-A-2007-39508. Preferred for convenience and environmental friendliness are corona treatment, flame treatment, atmospheric plasma treatment, and ultraviolet treatment (UV treatment).

### (Back Sheet for Solar Cell Modules)

The laminated film of the present invention may preferably be used as a back sheet for solar cell modules.

When used as a solar cell back sheet, the laminated film of the present invention may be used in the form of a laminated film as it is, or may be used with other layer laminated on the side of the laminated film of the present invention opposite the polymer layer.

Examples of such other layers include an easily bondable layer for sealant, a light reflecting layer, and a barrier layer. These layers may be provided by using known methods such as coating and bonding.

### (Solar Cell Module)

The solar cell module of the present invention has a form including a solar cell back sheet using the laminated film of the present invention. Specifically, the solar cell module of the present invention is structured to include a front sheet (may or may not be glass), a sealant, solar cells, a sealant, and a back sheet, which are laminated in this order, and sealed. The overcoat layer of the present invention represents the outermost layer of the module. With the solar cell back sheet of the present invention, the solar cell module of the present invention can have excellent weather resistance and lightfastness capability, and exhibits stable power generating performance over extended time periods.

### EXAMPLES

The present invention is described below in greater detail using Examples and Comparative Examples. Materials, amounts, proportions, and the contents and the procedures of the processes used in the following Examples may be appropriately varied, provided that such changes do not depart from the gist of the present invention. Accordingly, the scope of the present invention should not be narrowly interpreted within the limits of the concrete examples described below.

### Example 1

The support, the polymer layer, and the overcoat layer were laminated in the manner described below to produce a laminated sheet for solar cell modules.

### (Support)

### <Support-1>

### —Polyethylene Support—

A polyethylene sheet having a thickness of 200 μm (a 0.2-mm thick polyethylene sheet; Murakami Co., Ltd.) was used as a polyethylene support (hereinafter, also referred to as “PE support”).

### <Support-2>

### —Isotactic Polypropylene Support—

A polypropylene sheet having a thickness of 200 μm (PP craft film, PF-11, Acrysunday) was used as a polypropylene support (hereinafter, also referred to as “PP support”).

### <Support-3>

### —Fabrication of Syndiotactic Polypropylene Support—

A syndiotactic polypropylene support was produced as follows.

By using the procedures described in JP-A-2-274763, a syndiotactic polypropylene was obtained through bulk polymerization of propylene in the presence of hydrogen using a catalyst formed of diphenylmethylene(cyclopentadienyl)fluorenylzirconium dichloride and methylaluminoxane. The syndiotactic polypropylene (H-SPP) had an intrinsic viscosity of 1.39 dl/g as measured in a 135° C. tetralin solution, a melt flow index of 3.2 g/10 min, a crystallization peak temperature of 74.8° C. as measured by differential scanning calorimetry, and a syndiotactic pentad fraction of 76.7% as measured by ¹³C-NMR. The obtained syndiotactic polypropylene (80 parts by mass) was then mixed with isotactic homopolypropylene (Mitsui Toatsu Kagaku JHH-G: MFI 8 g/10 min; 20 parts by mass), and deposited with an extruder equipped with a downward T-die (φ=40 mm) at an extrusion temperature of 210° C. and a cooling roll temperature of 30° C. to obtain a 250 μm-thick syndiotactic polypropylene support (hereinafter, also referred to as “S-PP support”) sheet.

### <Surface Treatment>

Surface treatment was performed on one surface of the support by using any of the following methods. The conditions of each surface treatment are as follows.

### [Corona Treatment]

Device: Solid State Corona Treatment Device, Model 6KVA, Pillar; the gap clearance between electrode and dielectric roll: 1.6 mm

Process frequency: 9.6 kHz

Processing rate: 8 m/min

Process intensity: 0.75 kV·A·min/m²

### [Ultraviolet Treatment]

Light source: Low-pressure mercury lamp

Distance: 20 cm

Atmosphere: Atmospheric pressure

Process time: 30 s

### [Flame Treatment]

Burner: Box-shaped burner with a slit-like nozzle

Back roll: Ceramic back roll with a diameter of 300 mm

Flame treatment gas: Propane gas, propane gas/air=1/17 (volume ratio)

Gap: Set to allow the support to pass 10 mm above the tip of the inner flame

Processing rate: 50 m/min

### [Low-Pressure Plasma Treatment]

Pressure: 1.5 Torr

Atmospheric gas: Air

Discharge frequency: 13.56 MHz

Process intensity: 500 W·min/m²

### [Atmospheric Plasma Treatment]

Pressure: 750 Torr

Atmospheric gas: Argon

Discharge frequency: 5 KHz

Process intensity: 500 W·min/m²

### (Formation of Polymer Layer (Lightfastness Imparting Layer))

### —Preparation of Titanium Dioxide Dispersion—

The components of the composition below were mixed, and the mixture was dispersed with a dyno mill-type disperser for 1 hour. The composition of the titanium dioxide dispersion is as follows.
Titanium dioxide (volume average particle size=0.28 μm): 40 parts by mass; (Tipaque CR95, Ishihara Sangyo; solid content of 100 mass %)
Polyvinyl alcohol aqueous solution (10 mass %): 20.0 parts by mass; (PVA-105, Kuraray)
Surfactant (Demol EP, Kao Corporation; solid content of 25 mass %): 0.5 parts by mass
Distilled water: 39.5 parts by mass

### —Preparation of Coating Solution for Polymer Layer—

The components of the composition below were mixed to prepare a coating solution for polymer layer.
Distilled water: 408.8 parts by mass
Bonron XPS-002 (39 mass %): 363.7 parts by mass; (acryl binder (PA-1) from Mitsui Chemicals)
Titanium dispersion prepared above: 494.0 parts by mass
Epocros WS-700 (25 mass %): 112.0 parts by mass; (oxazoline-based crosslinker from Nippon Shokubai Co., Ltd.)
Diammonium hydrogen phosphate (35 mass %): 12.0 parts by mass
Fluorosurfactant (1 mass %): 18.2 parts by mass (sodium (3, 3, 4, 4, 5, 5, 6, 6 nonafluoro) 2-sulfonateoxysuccinate)

### —Application of Coating Solution for Polymer Layer—

The coating solution for polymer layer was applied to the corona treated surface of the support-1 (PE support) in 5.2 g/m² in terms of a binder amount, and dried at 180° C. for 1 min to form a polymer layer having a dry thickness of about 7.0 μm.

### (Formation of Overcoat Layer)

### —Preparation of Coating Solution for Overcoat Layer—

The components of the composition below were mixed to prepare a coating solution for the overcoat layer. The composition of the coating solution for overcoat layer is as follows.
Distilled water: 498.0 parts by mass
Fluorosurfactant (5 mass %): 7.2 parts by mass (sodium (3, 3, 4, 4, 5, 5, 6, 6 nonafluoro) 2-sulfonateoxysuccinate)
Snowtex UP (2 massa): 23.5 parts by mass (colloidal silica from Nissan Chemical Industries)
TSL 8340 (2 mass %): 23.5 parts by mass (amino silane coupling agent from Momentive Performance Materials)
Chemipearl W950 (5 mass %): 124.5 parts by mass (polyolefinic lubricant from Mitsui Chemicals)
Ceranate WSA-1070 (39 mass %): 207.0 parts by mass (silicone-based binder (PS-1) from DIC)
Diammonium hydrogen phosphate (35 mass %): 6.4 parts by mass
Epocros WS-700 (25 mass %): 59.8 parts by mass (oxazoline-based crosslinker from Nippon Shokubai Co., Ltd.)
Ethanol: 50.0 parts by mass

### —Application of Coating Solution for Overcoat Layer—

The obtained coating solution for overcoat layer was applied to the polymer layer on the support-1 in 2.0 g/m² in terms of a binder amount, and dried at 180° C. for 1 min to form an overcoat layer having a dry thickness of about 2 μm.

A laminated sheet for solar cell modules of Example 1 was produced with the PE support, the polymer layer, and the overcoat layer laminated in this order as above.

The sample was evaluated as follows. The results are presented in Table 1.

### (Evaluations)

### <Optical Density>

The laminated film was measured for light transmittance T1 at 350 nm. The sample was also measured for light transmittance T2 at 350 nm after removing the polymer layer and the overcoat layer. A Shimadzu spectrophotometer UV-3100 was used for the measurements. Optical density OD was then calculated from the measured values by using the following equation.

OD=Log(100/T1)−Log(100/T2)

Here, Log is the logarithm to base 10, and T1 and T2 are in percent. The polymer layer and the overcoat layer were removed by dissolving the film with an organic solvent.

### <Surface State>

The surface state of the sample was visually inspected, and evaluated according to the following evaluation criteria. The sample was deemed to be practical when it was rated 4 or 5 in the scale.

5: No nonuniformity or cissing was observed

4: Nonuniformity was present but was negligible, and cissing was absent

3: Some nonuniformity was observed, but cissing was absent

2: Nonuniformity was clearly visible, and cissing was observed in parts of the film (less than 10/m²)

1: Nonuniformity was clearly visible, and cissing was observed in 10/m² or more

### <Lightfastness>

Each back sheet sample was measured for YI value (YI-1) with a spectrocolorimeter (Spectro Color Meter SE 2000 available from Nippon Denshoku Industries). The back sheet sample was then irradiated with UV light at an illuminance of 900 W/m² for 48 hours with a lightfastness tester (Eye Super UV Tester W-151 available from Iwasaki Electric). UV light irradiation was performed under 63° C., 50% relative humidity conditions.

The back sheet sample was then measured for YI value (YI-2) with the spectrocolorimeter (Spectro Color Meter SE 2000, Nippon Denshoku Industries Co., Ltd.).

The measured values were used to determine YI=(YI-2)−(YI-1) as an index of the extent of coloring of the back sheet sample. The sample was then rated on the basis of its YI value according to the following evaluation criteria. The sample was deemed to be practical when it was rated 3 to 5 in the scale.

5: YI value of less than 3

4: YI value of 3 or more and less than 5

3: YI value of 5 or more and less than 10

2: YI value of 10 or more and less than 20

1: YI value of 20 or more

### <Adhesion>

(1) Adhesion before Exposure to Wet Heat

The coating layer surface of each sample was streaked in 6×6 patterns with a single blade razor to form 25 squares. A Mylar tape (polyester tape) was then attached to this surface, and detached by being manually pulled in 180° direction along the sample surface. From the number of detached squares, the adhesion of the back layer was rated according to the following evaluation criteria. The sample was deemed to be practical when it was rated 4 or 5 in the scale.

5: No square detached (0 square)

4: Less than 0.5 squares detached

3: 0.5 or more and less than 2 squares detached

2: 2 or more and less than 10 squares detached

1: 10 or more squares detached

(2) Adhesion after Exposure to Wet Heat (Weather Resistance)

Each sample was maintained under 120° C., 100% relative humidity conditions for 48 hours, and the humidity was adjusted under 25° C., 60% relative humidity conditions for 1 hour. The adhesion was then evaluated in the manner described above.

### Examples 2 to 4, and Comparative Examples 1 and 2

Samples of Examples 2 to 4 and Comparative Examples 1 and 2 were produced in the same manner as in Example 1, except that the titanium oxide content in the polymer layer was adjusted to vary the optical density as shown in Table 1. The obtained samples were evaluated in the same manner as in Example 1. The results are presented in Table 1.

### Example 5, and Comparative Examples 3 and 4

Samples of Example 5 and Comparative Examples 3 and 4 were produced in the same manner as in Example 1, except that the binders shown in Table 1 were used for the overcoat layer. The obtained samples were evaluated in the same manner as in Example 1. The results are presented in Table 1.

### Examples 6 to 9

Samples of Examples 6 to 9 were produced in the same manner as in Example 1, except that the support was subjected to the surface treatments shown in Table 1. The obtained samples were evaluated in the same manner as in Example 1. The results are presented in Table 1.

### Examples 10 to 13

Samples of Examples 10 to 13 were produced in the same manner as in Example 1, except that the binders shown in Table 1 were used for the polymer layer. The obtained samples were evaluated in the same manner as in Example 1. The results are presented in Table 1.

### Example 14

A sample of Example 14 was produced in the same manner as in Example 1, except that a dispersion of the compound A-1 below was used in place of the titanium dispersion. The obtained sample was evaluated in the same manner as in Example 1. The results are presented in Table 1. The UV absorber used was prepared by dispersing compound A-1 as follows.

### <Preparation of Compound A-1 Dispersion>

### —Preparation of Compound (A−1) Dispersion—

Compound (A−1) (18.94 parts by mass) was added to a mixed solvent of ethyl acetate (35.4 parts by mass) and tetrahydrofuran (8.8 parts by mass). The mixture was heated to 50° C., and stirred for 10 min to prepare an oil-phase solution of compound (A−1).

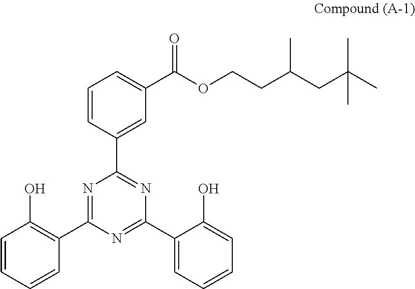 [SMILES: CC(CCOC(=O)c1cccc(-c2nc(-c3ccccc3O)nc(-c3ccccc3O)n2)c1)CC(C)(C)C]

Thereafter, distilled water (116.5 parts by mass) was added to a 400-cc stainless-steel container. After heating the water to 90° C., Kuraray Poval PVA-205 (polyvinyl alcohol, Kuraray; 20.5 parts by mass) was added, and dissolved by being stirred at 90° C. for 3 hours to prepare an aqueous-phase solution.

The oil-phase solution prepared above was added to the aqueous-phase solution while stirring the aqueous-phase solution at 500 rpm with a dissolver. The mixture was further stirred for 5 min to obtain a homogenous solution. This solution was stirred at 20,000 rpm for 10 min with a dissolver to obtain an emulsion. The average particle size of the obtained emulsion (emulsion 1) was measured with a laser/scattering particle size distribution measurement device LA950 (Horiba Ltd.). The emulsion had a median size of 120 nm.

The organic solvent was evaporated from the emulsion 1 with an evaporator to obtain dispersion 1. Gas chromatography measured the residual organic solvent to be 0.7 mass % or less. The concentration of the compound A-1 was 13 mass %. The median size of the dispersed particles was found to be 121 nm after an average particle size measurement performed in the manner described above.

### Examples 15 to 18, and Comparative Examples 5 and 6

Samples of Examples 15 to 18 and Comparative Examples 5 and 6 were produced in the same manner as in Example 1, except that support-2 was used, and that the optical density was varied as shown in Table 1. The obtained samples were evaluated in the same manner as in Example 1. The results are presented in Table 1.

### Example 19, and Comparative Examples 7 and 8

Samples of Example 19, and Comparative Examples 7 and 8 were produced in the same manner as in Example 1, except that support-2 was used, and that the binders shown in Table 1 were used for the overcoat layer. The obtained samples were evaluated in the same manner as in Example 1. The results are presented in Table 1.

### Examples 20 to 23

Samples of Examples 20 to 23 were produced in the same manner as in Example 1, except that support-2 was used, and that the support was subjected to the surface treatments shown in Table 1. The obtained samples were evaluated in the same manner as in Example 1. The results are presented in Table 1.

### Examples 24 to 27, and Comparative Examples 9 and 10

Samples of Examples 24 to 27, and Comparative Examples 9 and 10 were produced in the same manner as in Example 1, except that support-3 was used, and that the optical density was varied as shown in Table 1. The obtained samples were evaluated in the same manner as in Example 1. The results are presented in Table 1.

### Example 28, and Comparative Examples 11 and 12

Samples of Example 28, and Comparative Examples 11 and 12 were produced in the same manner as in Example 1, except that support-3 was used, and that the binders shown in Table 1 were used for the overcoat layer. The obtained samples were evaluated in the same manner as in Example 1. The results are presented in Table 1.

### Examples 29 to 32

Samples of Examples 29 to 32 were produced in the same manner as in Example 1, except that support-3 was used, and that the support was subjected to the surface treatments shown in Table 1. The obtained samples were evaluated in the same manner as in Example 1. The results are presented in Table 1.

TABLE 1

| | | | Polymer layer | | | | | | Evaluation | | | |
|---|---|---|---|---|---|---|---|---|---|---|---|---|
| | | | | | UV absorber | | Thick- | Overcoat | | Light- | | Weather |
| Sample | Support | | | UV | content (mass | Optical | ness | layer | Surface | fast- | Adhe- | resis- |
| No. | Type | Surface treatment | Binder | absorber | % wrt binder) | density | (μm) | Binder | state | ness | sion | tance |
| Com. | Support-1 | Corona treatment | PA-1 | TiO₂ | 0 | 0 | 5.2 | PS-1 | 5 | 1 | 5 | 4 |
| Ex. 1 | | | | | | | | | | | | |
| Com. | Support-1 | Corona treatment | PA-1 | TiO₂ | 97 | 1.8 | 6.4 | PS-1 | 5 | 2 | 5 | 4 |
| Ex. 2 | | | | | | | | | | | | |
| Ex. 1 | Support-1 | Corona treatment | PA-1 | TiO₂ | 140 | 2.6 | 7.0 | PS-1 | 5 | 4 | 5 | 4 |
| Ex. 2 | Support-1 | Corona treatment | PA-1 | TiO₂ | 113 | 2.1 | 6.7 | PS-1 | 5 | 3 | 5 | 4 |
| Ex. 3 | Support-1 | Corona treatment | PA-1 | TiO₂ | 167 | 3.1 | 7.3 | PS-1 | 5 | 5 | 5 | 4 |
| Ex. 4 | Support-1 | Corona treatment | PA-1 | TiO₂ | 221 | 4.1 | 8.0 | PS-1 | 4 | 5 | 4 | 4 |
| Ex. 5 | Support-1 | Corona treatment | PA-1 | TiO₂ | 140 | 2.6 | 7.0 | PF-1 | 5 | 4 | 5 | 4 |
| Com. | Support-1 | Corona treatment | PA-1 | TiO₂ | 140 | 2.6 | 7.0 | PA-2 | 5 | 4 | 5 | 2 |
| Ex. 3 | | | | | | | | | | | | |
| Com. | Support-1 | Corona treatment | PA-1 | TiO₂ | 140 | 2.6 | 7.0 | PU-1 | 5 | 4 | 5 | 1 |
| Ex. 4 | | | | | | | | | | | | |
| Ex. 6 | Support-1 | UV treatment | PA-1 | TiO₂ | 140 | 2.6 | 7.0 | PS-1 | 5 | 4 | 5 | 4 |
| Ex. 7 | Support-1 | Flame treatment | PA-1 | TiO₂ | 140 | 2.6 | 7.0 | PS-1 | 5 | 4 | 5 | 4 |
| Ex. 8 | Support-1 | Low-pressure | PA-1 | TiO₂ | 140 | 2.6 | 7.0 | PS-1 | 5 | 4 | 5 | 4 |
| | | plasma treatment | | | | | | | | | | |
| Ex. 9 | Support-1 | Atmospheric | PA-1 | TiO₂ | 140 | 2.6 | 7.0 | PS-1 | 5 | 4 | 5 | 4 |
| | | plasma treatment | | | | | | | | | | |
| Ex. 10 | Support-1 | Corona treatment | PO-1 | TiO₂ | 140 | 2.6 | 7.0 | PS-1 | 5 | 4 | 5 | 4 |
| Ex. 11 | Support-1 | Corona treatment | PE-1 | TiO₂ | 140 | 2.6 | 7.0 | PS-1 | 5 | 4 | 5 | 4 |
| Ex. 12 | Support-1 | Corona treatment | PU-1 | TiO₂ | 140 | 2.6 | 7.0 | PS-1 | 5 | 4 | 5 | 4 |
| Ex. 13 | Support-1 | Corona treatment | PS-1 | TiO₂ | 140 | 2.6 | 7.0 | PS-1 | 5 | 4 | 5 | 5 |
| Ex. 14 | Support-1 | Corona treatment | PA-1 | Compound | 140 | 2.6 | 7.0 | PS-1 | 5 | 4 | 5 | 4 |
| | | | | A-1 | | | | | | | | |
| Com. | Support-2 | Corona treatment | PA-1 | TiO₂ | 0 | 0 | 5.2 | PS-1 | 5 | 1 | 5 | 4 |
| Ex. 5 | | | | | | | | | | | | |
| Com. | Support-2 | Corona treatment | PA-1 | TiO₂ | 92 | 1.7 | 6.4 | PS-1 | 5 | 2 | 5 | 4 |
| Ex. 6 | | | | | | | | | | | | |
| Ex. 15 | Support-2 | Corona treatment | PA-1 | TiO₂ | 113 | 2.1 | 6.7 | PS-1 | 5 | 3 | 5 | 4 |
| Ex. 16 | Support-2 | Corona treatment | PA-1 | TiO₂ | 129 | 2.4 | 6.9 | PS-1 | 5 | 4 | 5 | 4 |
| Ex. 17 | Support-2 | Corona treatment | PA-1 | TiO₂ | 178 | 3.3 | 7.5 | PS-1 | 5 | 5 | 5 | 4 |
| Ex. 18 | Support-2 | Corona treatment | PA-1 | TiO₂ | 221 | 4.1 | 8.0 | PS-1 | 4 | 5 | 4 | 4 |
| Ex. 19 | Support-2 | Corona treatment | PA-1 | TiO₂ | 140 | 2.6 | 7.0 | PF-1 | 5 | 4 | 5 | 4 |
| Com. | Support-2 | Corona treatment | PA-1 | TiO₂ | 140 | 2.6 | 7.0 | PA-2 | 5 | 4 | 5 | 2 |
| Ex. 7 | | | | | | | | | | | | |
| Com. | Support-2 | Corona treatment | PA-1 | TiO₂ | 140 | 2.6 | 7.0 | PU-1 | 5 | 4 | 5 | 1 |
| Ex. 8 | | | | | | | | | | | | |
| Ex. 20 | Support-2 | UV treatment | PA-1 | TiO₂ | 140 | 2.6 | 7.0 | PS-1 | 5 | 4 | 5 | 4 |
| Ex. 21 | Support-2 | Flame treatment | PA-1 | TiO₂ | 140 | 2.6 | 7.0 | PS-1 | 5 | 4 | 5 | 4 |
| Ex. 22 | Support-2 | Low-pressure | PA-1 | TiO₂ | 140 | 2.6 | 7.0 | PS-1 | 5 | 4 | 5 | 4 |
| | | plasma treatment | | | | | | | | | | |
| Ex. 23 | Support-2 | Atmospheric | PA-1 | TiO₂ | 140 | 2.6 | 7.0 | PS-1 | 5 | 4 | 5 | 4 |
| | | plasma treatment | | | | | | | | | | |
| Com. | Support-3 | Corona treatment | PA-1 | TiO₂ | 0 | 0 | 5.2 | PS-1 | 5 | 1 | 5 | 4 |
| Ex. 9 | | | | | | | | | | | | |
| Com. | Support-3 | Corona treatment | PA-1 | TiO₂ | 97 | 1.8 | 6.4 | PS-1 | 5 | 2 | 5 | 4 |
| Ex. 10 | | | | | | | | | | | | |
| Ex. 24 | Support-3 | Corona treatment | PA-1 | TiO₂ | 118 | 2.2 | 6.7 | PS-1 | 5 | 3 | 5 | 4 |
| Ex. 25 | Support-3 | Corona treatment | PA-1 | TiO₂ | 151 | 2.8 | 7.1 | PS-1 | 5 | 4 | 5 | 4 |
| Ex. 26 | Support-3 | Corona treatment | PA-1 | TiO₂ | 183 | 3.4 | 7.6 | PS-1 | 5 | 5 | 5 | 4 |
| Ex. 27 | Support-3 | Corona treatment | PA-1 | TiO₂ | 237 | 4.4 | 8.2 | PS-1 | 4 | 5 | 4 | 4 |
| Ex. 28 | Support-3 | Corona treatment | PA-1 | TiO₂ | 140 | 2.6 | 7.0 | PF-1 | 5 | 4 | 5 | 4 |
| Com. | Support-3 | Corona treatment | PA-1 | TiO₂ | 140 | 2.6 | 7.0 | PA-2 | 5 | 4 | 5 | 2 |
| Ex. 11 | | | | | | | | | | | | |
| Com. | Support-3 | Corona treatment | PA-1 | TiO₂ | 140 | 2.6 | 7.0 | PU-1 | 5 | 4 | 5 | 1 |
| Ex. 12 | | | | | | | | | | | | |
| Ex. 29 | Support-3 | UV treatment | PA-1 | TiO₂ | 140 | 2.6 | 7.0 | PS-1 | 5 | 4 | 5 | 4 |
| Ex. 30 | Support-3 | Flame treatment | PA-1 | TiO₂ | 140 | 2.6 | 7.0 | PS-1 | 5 | 4 | 5 | 4 |
| Ex. 31 | Support-3 | Low-pressure | PA-1 | TiO₂ | 140 | 2.6 | 7.0 | PS-1 | 5 | 4 | 5 | 4 |
| | | plasma treatment | | | | | | | | | | |
| Ex. 32 | Support-3 | Atmospheric | PA-1 | TiO₂ | 140 | 2.6 | 7.0 | PS-1 | 5 | 4 | 5 | 4 |
| | | plasma treatment | | | | | | | | | | |

PA-1: Bonron XPS-002, Mitsui Chemicals acrylic binder, solid content 39 mass %
PO-1: Arrowbase SE-1013N, Unitika polyolefinic binder, solid content 20 mass %
PE-1: Finetex ES650, DIG polyester-based binder, solid content 29 mass %
PU-1: Olester UD350, Mitsui Chemicals polyurethane-based binder, solid content 38 mass %
PS-1: Ceranate WSA-1070, DIG, silicone-based binder, solid content 40 mass %
PF-1: Obbligato SW0011F, AGC Coat-Tech fluorine-based binder, solid content 39 mass %
PA-2: Jurymer ET-410, Ninon Junyaku acrylic binder, solid content 30 mass %

As can be seen in Table 1, high weather resistance and high lightfastness were obtained in Examples 1 to 32. The laminated films obtained in Examples 1 to 32 also had excellent adhesion between the layers, and the surface state was desirable. It can also be seen that the effects were desirable regardless of whether the polyolefin used for the support was polyethylene or polypropylene.

On the other hand, the optical density was less than 2.0 in the polymer layers of Comparative Examples 1, 2, 5, 6, 9, and 10, and the lightfastness was insufficient. Weather resistance was poor in Comparative Examples 3, 4, 7, 8, 11, and 12 in which silicone-based resin or fluorine-based resin was not used as the binder of the overcoat layer.

### Examples 33 to 64

Solar cell back sheets were produced with an easily bondable layer provided on the surface of the laminated films of Examples 1 to 32 opposite the polymer layer and the overcoat layer.

### —Preparation of Coating Solution for Easily Bondable Layer—

The components of the composition below were mixed to prepare a coating solution for easily bondable layer.

### (Composition of Coating Solution for Easily Bondable Layer)

Titanium dispersion prepared above: 300 parts by mass

Distilled water: 40 parts by mass

Epocros WS700 (25 mass %): 100 parts by mass (oxazoline-based crosslinker from Nippon Shokubai Co., Ltd.)

Arrowbase SE-1013N (20 mass %): 550 parts by mass (polyolefinic binder (P0-1) from Unitika)

Fluorosurfactant (1 mass %): 10 parts by mass (Sodium (3, 3, 4, 4, 5, 5, 6, 6 nonafluoro) 2-sulfonateoxysuccinate)

### —Application of Coating Solution for Easily Bondable Layer—

The laminated films of Examples 1 to 32 were each subjected to the corona treatment on the surface opposite the polymer layer and the overcoat layer. The coating solution for easily bondable layer was then applied to this surface of the laminated film (the surface opposite the polymer layer and the overcoat layer) in 3.0 g/m² in terms of a binder amount, and dried at 180° C. for 1 min to form an easily bondable layer having a dry thickness of about 4.5

### Examples 65 to 96

### Fabrication of Solar Cell Module

A hardened glass (3 mm in thickness), an EVA sheet (Mitsui Chemicals Fabro SC50B), crystalline solar cells, an EVA sheet (Mitsui Chemicals Fabro SC50B), and the solar cell back sheets of Examples 33 to 64 were laminated in this order, and hot pressed with a vacuum laminator (Vacuum Laminator from Nisshinbo) to bond the layers with EVA. The back sheet was disposed in such an orientation that the easily bondable layer contacted the EVA sheet. The EVA was bonded under the following conditions.

The layers were temporarily bonded under applied pressure for 2 min after vacuuming performed at 128° C. for 3 min with a vacuum laminator. The film was then dried in a dry oven at 150° C. for 30 min to permanently bond the layers.

The fabricated solar cell modules 1 to 30 were operated to generate electricity. All modules demonstrated favorable electricity generation performance, and were desirable as solar cells.

The present invention can provide a laminated film having both weather resistance and lightfastness. The laminated film of the present invention is desirable as a back sheet for solar cell modules used in a severe environment such as outdoor, and is highly applicable in industry.

While the present invention has been described in detail and with reference to specific embodiments thereof, it will be apparent to one skilled in the art that various changes and modifications can be made therein without departing from the spirit and scope thereof.

The present disclosure relates to the subject matter contained in International Application No. PCT/JP2014/056863, filed on Mar. 14, 2014; and Japanese Patent Application No. 2013-053972 filed on Mar. 15, 2013, the contents of which are expressly incorporated herein by reference in their entirety. All the publications referred to in the present specification are also expressly incorporated herein by reference in their entirety.

The foregoing description of preferred embodiments of the invention has been presented for purposes of illustration and description, and is not intended to be exhaustive or to limit the invention to the precise form disclosed. The description was selected to best explain the principles of the invention and their practical application to enable others skilled in the art to best utilize the invention in various embodiments and various modifications as are suited to the particular use contemplated. It is intended that the scope of the invention not be limited by the specification, but be defined claims.

What is claimed is:

1. A laminated film containing a support, a polymer layer laminated on at least one surface of the support, and an overcoat layer laminated on a side of the polymer layer opposite the side with the support, wherein:
the support contains polyolefin as a main component,
the polymer layer has an optical density of 2.0 or more at 350 nm, and
the overcoat layer contains at least one of silicone-based resin and fluorine-based resin.

2. The laminated film according to claim 1, wherein the polymer layer contains at least one binder resin selected from acrylic resin, polyester-based resin, polyurethane-based resin, polyolefinic resin, and silicone-based resin.

3. The laminated film according to claim 1, wherein the polymer layer contains a UV absorber and a binder resin, the UV absorber being contained in 50 to 300 mass % with respect to the total mass of the binder resin.

4. The laminated film according to claim 1, wherein the polymer layer has an optical density of 2.5 or more at 350 nm.

5. The laminated film according to claim 1, wherein the polymer layer has an average thickness of 0.3 to 18 μm.

6. The laminated film according to claim 1, wherein the polymer layer is formed by being coated.

7. The laminated film according to claim 1, wherein at least one surface of the support is surface treated.

8. The laminated film according to claim 1, having a ΔYI of 10 or less, wherein the ΔYI represents an extent of yellowing of the laminated film with the formula (YI-2)−(YI-1), in which (YI-1) is the yellow chromaticity of the laminated film before ultraviolet irradiation, and (YI-2) is the yellow chromaticity of the laminated film after irradiation of ultraviolet light at an illuminance of 900 W/m² for 48 hours.

9. A solar cell back sheet having a laminated film, wherein:
the laminated film contains a support, a polymer layer laminated on at least one surface of the support, and an overcoat layer laminated on a side of the polymer layer opposite the side with the support,
the support contains polyolefin as a main component,
the polymer layer has an optical density of 2.0 or more at 350 nm, and
the overcoat layer contains at least one of silicone-based resin and fluorine-based resin.

10. A solar cell module having a solar cell back sheet having a laminated film, wherein:
the laminated film contains a support, a polymer layer laminated on at least one surface of the support, and an overcoat layer laminated on a side of the polymer layer opposite the side with the support,
the support contains polyolefin as a main component,
the polymer layer has an optical density of 2.0 or more at 350 nm, and
the overcoat layer contains at least one of silicone-based resin and fluorine-based resin.
